(19) United States
(12) Patent Application Publication
(10) Pub. No.: US 2007/0278496 A1
(43) Pub. Date: Dec. 6, 2007

(54) LIGHT EMITTING DIODE

(76) Inventors: Yuh-Ren Shieh, Hsinchu County (TW); Chuan-Cheng Tu, Taipei City (TW); Jen-Chau Wu, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/733,778

(22) Filed: Apr. 11, 2007

(30) Foreign Application Priority Data
Jun. 5, 2006 (TW) 095119872

(51) Int. Cl. H01L 33/00

(52) U.S. Cl. 257/79

(57) ABSTRACT

A light emitting diode is disclosed. The light emitting diode includes a substrate, a thermal spreading layer disposed on the bottom of the substrate, a soldering layer disposed on the bottom of the thermal spreading layer, a barrier layer disposed between the thermal spreading layer and the soldering layer, and a light emitting layer disposed on top of the substrate.

### BACKGROUND OF THE INVENTION

1. Field of the Invention

The invention relates to a light emitting diode, and more particularly, to a light emitting diode having a thermal spreading layer.

2. Description of the Prior Art

Recently, new application fields of high illumination light emitting diodes (LEDs) have been developed. Different from a common incandescent lamp, a cold illumination LED has the advantages of low power consumption, long device lifetime, no idling time, and quick response speed. In addition, since the LED also has the advantages of small sizes, being suitable for mass production, and being easily fabricated as a tiny device or an array device, it has been widely applied in display apparatuses and indicating lamps of information, communication, and consumer electronic products. The LEDs are not only utilized in outdoor traffic signal lamps and various outdoor displays, but also very important components in the automotive industry. Furthermore, the LEDs also work well in portable products, such as backlights of cell phones and personal data assistants. The LED has become a necessary key component in the very popular liquid crystal display because it is the best choice when selecting the light source of the backlight module.

Referring to FIG. 1, the light-emitting diode 10 includes a substrate 11, a distributed Bragg reflector (DBR) 12, a light emitting layer 13, a p-type semiconductor layer 14, a p-type electrode 15, a soldering layer 18 below the substrate 11, a heat sink (not shown) connecting the soldering layer 18, and an n-type electrode 16 located under the soldering layer 18. The substrate 11 is an n-type GaAs substrate, and the DBR 12 is a structure of multiple reflective layers for reflecting light. The light emitting layer 13 comprises an n-type AlGaInP lower cladding layer, an AlGaInP active layer, and a p-type AlGaInP upper cladding layer. The p-type semiconductor layer 14 is an ohmic contact layer, whose material can be AlGaAs, AlGaInP, or GaAsP. The p-type electrode 15 and the n-type electrode 16 are metal electrodes for wire bonding.

In order to increase the efficiency of the light emitting diode, a conventional method often involves a soldering layer under the bottom of the substrate, in which the soldering layer facilitates a direct contact of a heat sink and the substrate, thereby reducing the distance of thermal dissipation of the device. Nevertheless, when a soldering process is performed on the light emitting diode, an inter-mixing will often occur between the soldering layer and the other layers. Consequently, problems can arise, including the generation of air bubbles or localized hot spots that can result in a burn-out phenomenon. Additionally, an irregular dissipation path can be created in case that the surface of the substrate is uneven, which further increases the soldering difficulty of the light emitting diode. Hence, finding a method to effectively increase the reliability of light emitting diodes and ultimately reduce the occurrence of problems such as air bubbles and localized hot spots has become a critical task.

### SUMMARY OF THE INVENTION

It is an object of the present invention to provide a light emitting diode for solving the aforementioned problems.

In accordance with the present invention, a light emitting diode is disclosed. The light emitting diode includes a substrate having a top surface and a bottom surface, a thermal spreading layer disposed on the bottom surface of the substrate, a soldering layer disposed on the bottom surface of the thermal spreading layer, a barrier layer disposed between the thermal spreading layer and the soldering layer, and a light emitting layer disposed on the top surface of the substrate.

By disposing a thermal spreading layer composed of low thermal resistance or high thermal conductive material, the present invention is able to increase the heat dissipating ability of the light emitting diode, thereby improving the burn-out problem caused by air bubbles and localized hot spots generated during the soldering process of the light emitting diode. Additionally, the thermal spreading layer of the present invention can be further utilized as a buffer material between the substrate and the soldering layer, thereby improving the problem of uneven heat distribution inherent with the conventional art, which is often caused by uneven surface of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a structural diagram of a light-emitting diode in accordance with the prior art.

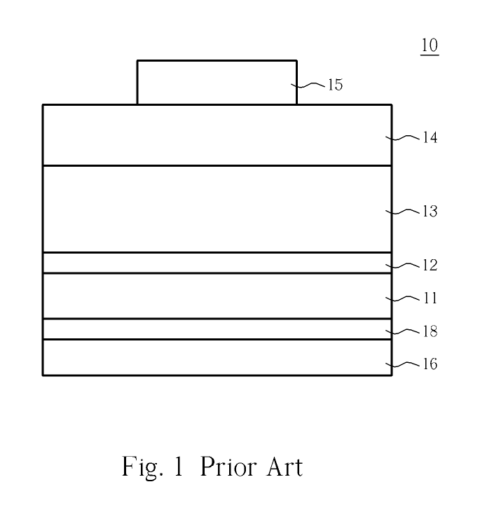

FIG. 2 is a perspective diagram illustrating the structure of a light emitting diode in accordance with a preferred embodiment of the present invention.

FIG. 3 is a diagram illustrating the thermal conductivity, thermal resistance ratio, and thermal concentration of the thermal spreading layer of a light emitting diode in accordance with the present invention.

FIG. 4 is a diagram illustrating the thermal conductivity, normalized temperature ratio, and thermal concentration of the thermal spreading layer of the light emitting diode in accordance with the present invention.

FIG. 5 is a diagram illustrating the thermal concentration, thermal resistance ratio, and thermal coefficient of the thermal spreading layer of the light emitting diode in accordance with the present invention.

FIG. 6 is a perspective diagram illustrating the structure of a light emitting diode in accordance with an embodiment of the present invention.

### DETAILED DESCRIPTION

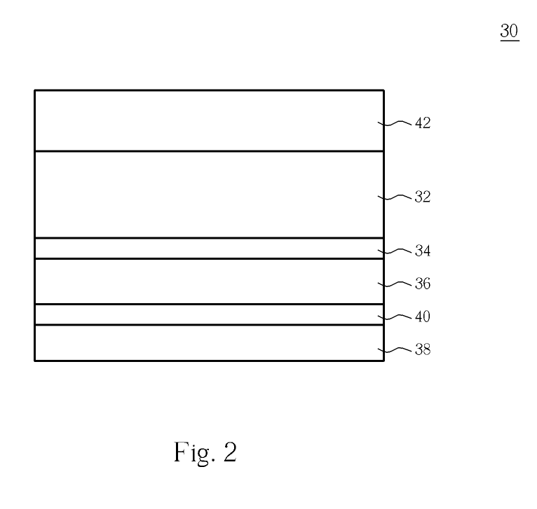

Referring to FIG. 2, a substrate 32 of conductive material is provided, in which the substrate 32 is a GaAs substrate or a carrier. Next, an adhesive layer 34 is formed on the bottom surface of the substrate 32, in which the adhesive layer 34 provides adequate adhesion and ohmic contact between a thermal spreading layer formed afterwards and the substrate 32. In accordance with the preferred embodiment of the present invention, the adhesive layer 34 comprises titanium, titanium alloy, chromium, chromium alloy, silver, silver alloy, aluminum, aluminum alloy, copper, copper alloy, or indium tin oxide.

Next, a thermal spreading layer 36 is disposed on the bottom surface of the adhesive layer 34, in which the thermal spreading layer 36 functions to reduce the thermal accumulation caused by inter-mixing between the rough surface of the substrate 32 and other layers. In accordance with the preferred embodiment of the present invention, the thermal spreading layer 36 comprises a material having lower heat resistance, such as a material lower than 5° C./W, or a material having high thermal conductivity, such as diamond, carbon nanotubes, silver, copper, gold, aluminum nitride, aluminum, nickel, iron, platinum, or beryllium oxide. Preferably, the thermal spreading layer 36 is utilized to reduce the thermal resistance and temperature of the light emitting diode 30, thereby preventing the burn-out problem commonly occurred in the conventional art when the light emitting diode is being soldered.

After the thermal spreading layer 36 is disposed, a barrier layer 40 is formed on the bottom surface of the thermal spreading layer 36, and a soldering layer 38 is formed on the bottom of the barrier layer 40 thereafter. The barrier layer 40 comprises titanium, platinum, tantalum, molybdenum, tungsten, radium, or rhodium, in which the barrier layer 40 functions to reduce the inter-mixing taking place between the thermal spreading layer 36 and the soldering layer 38. The soldering layer 38 comprises indium, lead, gold, tin, or alloy or eutectics selected from the group consisting of indium, lead, gold, and tin.

Next, a light emitting layer 42 is disposed on the top of the substrate 32, in which the light emitting layer 42 comprises an n-type AlGaInP lower cladding layer, an AlGaInP active layer, and a p-type AlGaInP upper cladding layer. Next, a heat sink or a package (both not shown) is attached to the bottom of the soldering layer 38 by a soldering process, thereby completing the manufacture of a light emitting diode 30.

Preferably, the thermal conductivity (k) of the thermal spreading layer 36 is directly related to the thermal concentration (C), thermal resistance ratio (Rsp %), and normalized temperature ratio of the light emitting diode 30.

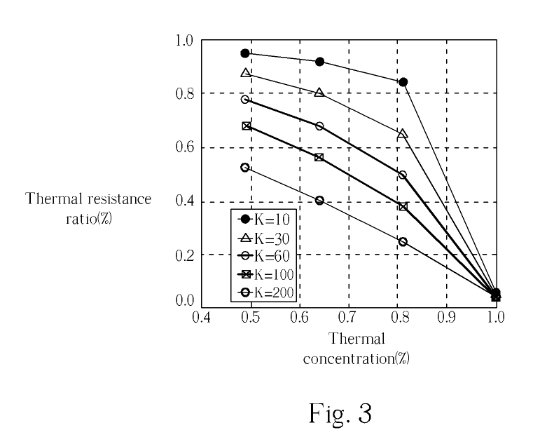

Referring to FIG. 3, the thermal resistance ratio is preferably directly proportional to the thermal resistance between a heat sink (not shown) and the light emitting diode 30, and inversely proportional to an overall thermal resistance (Rth) between the ambient environment and the light emitting diode 30. In other words, the thermal resistance ratio (Rsp %) will increase as the thermal resistance (Rsp) between the heat sink and the light emitting diode 30 increases, and will decrease as the overall thermal resistance (Rth) between the ambient environment and the light emitting diode 30 increases.

Additionally, the thermal concentration (C) is directly proportional to the thermal conductive area of the light emitting diode 30 and inversely proportional to the overall area of the light emitting diode 30. Hence, the thermal concentration of the light emitting diode 30 increases as the thermal conductive area of the light emitting diode 30 increases and decreases as the overall area of the light emitting diode 30 increases.

As shown in FIG. 3, under a same level of thermal concentration, the thermal resistance of the light emitting diode 30 decreases as the thermal conductivity of the thermal spreading layer 36 increases. In other words, by selecting a material with higher thermal conductivity to form the thermal spreading layer 36, the thermal resistance of the light emitting diode 30 can be reduced significantly, thereby increasing the heat dissipating ability of the light emitting diode 30.

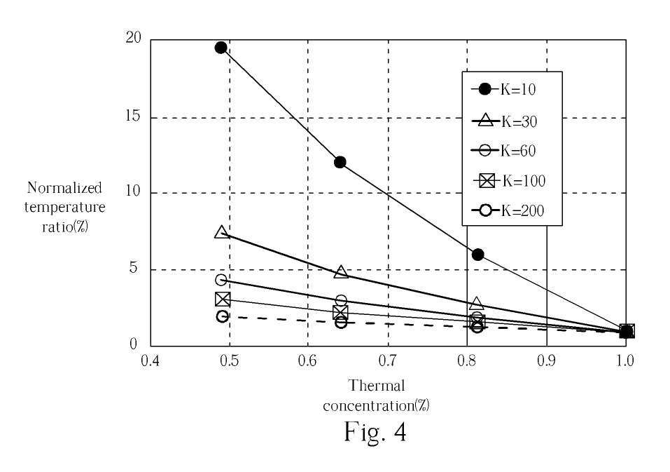

Referring to FIG. 4, under the same level of thermal concentration, the normalized temperature ratio of the light emitting diode 30 decreases as the thermal conductivity of the thermal spreading layer 36 increases. In other words, by selecting a material with higher thermal conductivity (k) to form the thermal spreading layer 36, the heat dissipating ability of the thermal spreading layer 36 can be significantly increased, thereby effectively reducing the temperature of the light emitting diode 30.

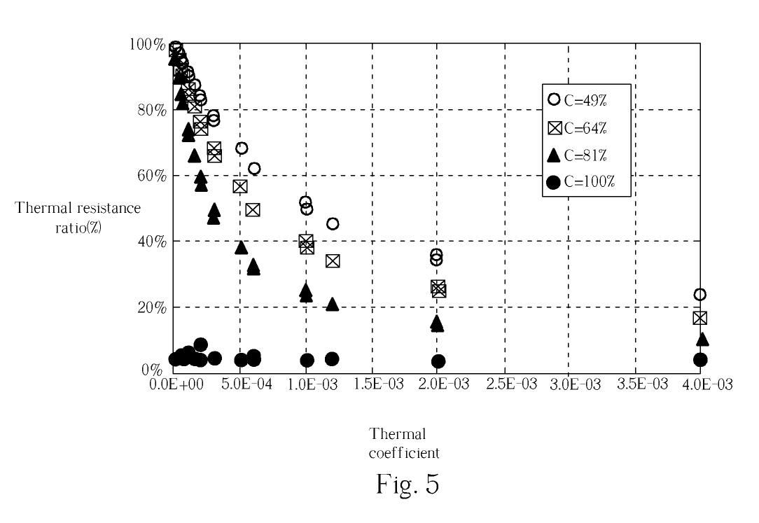

Referring to FIG. 5, the thermal coefficient is preferably directly proportional to the thermal conductivity (k) and thickness of the thermal spreading layer 36. As shown in FIG. 5, under the same level of thermal concentration, the thermal resistance ratio of the light emitting diode 30 decreases as the thermal coefficient increases. In other words, by increasing the thermal conductivity of the thermal spreading layer 36, or increasing the thickness of the thermal spreading layer 36, the present invention is able to increase the thermal coefficient (kt) of the light emitting diode 30 and decrease the thermal resistance ratio, thereby increasing the heat dissipating ability of the light emitting diode 30. In accordance with the preferred embodiment of the present invention, the thickness of the thermal spreading layer 36 is greater than 0.2 μm.

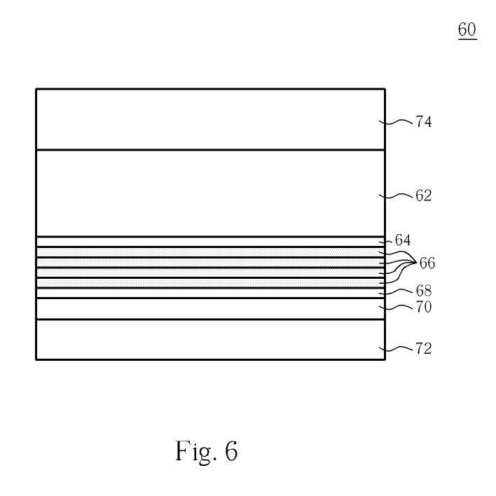

Referring to FIG. 6, a substrate 62 composed of conductive material is provided, in which the substrate 62 may be a GaAs substrate or a carrier. Next, an adhesive layer 64 is formed on the bottom of the substrate 62. The adhesive layer 64 functions to provide adequate adhesion and ohmic contact between a thermal spreading layer formed in a later process and the substrate 62. As described in the previous embodiment, the adhesive layer 64 is composed of titanium, titanium alloy, chromium, chromium alloy, silver, silver alloy, aluminum, aluminum alloy, copper, copper alloy, or indium tin oxide.

Next, a distributed Bragg reflector (DBR) 66 and a thermal spreading layer 68 are formed on the bottom of the adhesive layer 64. The distributed Bragg reflector 66 is a structure of the multiple reflective layers formed by overlapping aluminum arsenic (AlAs) and gallium arsenic (GaAs). The distributed Bragg reflector 66 functions to reflect the lights projected toward the substrate 62. The thermal spreading layer 68 comprises diamond, carbon nanotubes, silver, copper, gold, aluminum nitride, aluminum, nickel, iron, platinum, or beryllium oxide. Preferably, the thermal spreading layer 68 serves to reduce the thermal resistance and temperature of the light emitting diode 60. Next, a barrier layer 70 is formed on the bottom of the thermal spreading layer 68, and a soldering layer 72 is formed on the bottom of the barrier layer 70 thereafter. The barrier layer 70 comprises titanium, platinum, tantalum, molybdenum, tungsten, radium, or rhodium, in which the barrier layer 70 functions to reduce the inter-mixing takes place between the thermal spreading layer 68 and the soldering layer 72. The soldering layer 72 comprises of indium, lead, gold, tin, or alloy or eutectics selected from the group consisting of indium, lead, gold, and tin.

Next, a light emitting layer 74 is disposed on the top of the substrate 62, in which the light emitting layer 74 comprises an n-type AlGaInP lower cladding layer, an AlGaInP active layer, and a p-type AlGaInP upper cladding layer. Next, a heat sink or a package (both not shown) is attached to the bottom of the soldering layer 72 by a soldering process, thereby completing the manufacture of a light emitting diode 60.

Preferably, by disposing a thermal spreading layer composed of low thermal resistance or high thermal conductive material, the present invention is able to increase the heat dissipating ability of the light emitting diode, thereby avoiding the burn-out problem caused by air bubbles and localized hot spots generated during the soldering process of the light emitting diode. Additionally, the thermal spreading layer of the present invention can be further utilized as a buffer material between the substrate and the soldering layer, thereby alleviating the problem of uneven heat distribution from the conventional art, which is often caused by the uneven surface of the substrate.

Those skilled in the art will readily observe that numerous modifications and alterations of the device and method may be made while retaining the teachings of the invention.

What is claimed is:

1. A light emitting diode, comprising:
a substrate, having a top surface and a bottom surface;
a thermal spreading layer, disposed on the bottom surface of the substrate;
a soldering layer, disposed on the bottom surface of the thermal spreading layer;
a barrier layer, disposed between the thermal spreading layer and the soldering layer; and
a light emitting layer, disposed on the top surface of the substrate.

2. The light emitting diode of claim 1, wherein the substrate comprises a conductive material.

3. The light emitting diode of claim 1, wherein the thermal spreading layer comprises diamond, carbon nanotubes, silver, copper, gold, aluminum nitride, aluminum, nickel, iron, platinum, or beryllium oxide.

4. The light emitting diode of claim 3, wherein the thickness of the thermal spreading layer is greater than 0.2 micrometers.

5. The light emitting diode of claim 3, wherein the thermal resistance of the thermal spreading layer is less than 5° C./W.

6. The light emitting diode of claim 1 having a thermal resistance ratios (Rsp %), wherein the thermal resistance ratio is directly proportional to a thermal resistance (Rsp) between the light emitting diode and a heat sink, and inversely proportional to an overall thermal resistance (Rth) between the light emitting diode and the ambient environment.

7. The light emitting diode of claim 1 having a thermal concentration, wherein the thermal concentration is directly proportional to the conductive area of the light emitting diode and inversely proportional to the overall area of the light emitting diode.

8. The light emitting diode of claim 1, wherein a thermal coefficient (kt) of the light emitting diode is directly proportional to the thermal conductivity (k) and the thickness of the thermal spreading layer.

9. The light emitting diode of claim 1, wherein the soldering layer comprises indium, lead, gold, tin, or alloy or eutectics selected from the group consisting of indium, lead, gold, and tin.

10. The light emitting diode of claim 1, wherein the barrier layer comprises titanium, platinum, tantalum, molybdenum, tungsten, radium, or rhodium.

11. The light emitting diode of claim 1 further comprising an adhesive layer disposed between the substrate and the thermal spreading layer.

12. The light emitting diode of claim 11, wherein the adhesive layer comprises titanium, titanium alloy, chromium, chromium alloy, silver, silver alloy, aluminum, aluminum alloy, copper, copper alloy, or indium tin oxide.

13. The light emitting diode of claim 1 further comprising a distributed Bragg reflector disposed between the substrate and the soldering layer.
